(19) United States
(12) Patent Application Publication
(10) Pub. No.: US 2008/0160782 A1
(43) Pub. Date: Jul. 3, 2008

(54) Method for forming insulating film

(76) Inventors: Osamu Yamazaki, Hiroshima (JP); Takahiro Kotabe, Hiroshima (JP)

Correspondence Address: HARNESS, DICKEY & PIERCE, P.L.C., P.O. BOX 8910, RESTON, VA, 20195, US

(21) Appl. No.: 12/003,464

(22) Filed: Dec. 26, 2007

(30) Foreign Application Priority Data
Dec. 27, 2006 (JP) 2006-352065

(51) Int. Cl. H01L 21/31

(52) U.S. Cl. 438/761; 257/E21.24

(57) ABSTRACT

A method of forming an insulating film for enhancing the film and removing water and OH groups from the film efficiently. The method comprises steps of forming a second low dielectric constant insulating film having a thickness smaller than a desired thickness in a predetermined material gas atmosphere, carrying out O₂ gas treatment at the same substrate temperature and pressure as those in the step of forming the second low dielectric constant insulating film, carrying out residual unreacted material removal, uncombined bonds termination, or absorbed OH group removal, without air exposure, and forming a second cap insulating film. The steps of forming the second low dielectric constant insulating film, carrying out processes such as the residual unreacted material removal, and forming the second cap insulating film are repeated until a total thickness of the second low dielectric constant insulating film and the second cap insulating film reaches a desired level.

### CROSS REFERENCE TO RELATED APPLICATION

This Nonprovisional application claims priority under 35 U.S.C. §119(a) on Patent Application No. 2006-352065 filed in Japan on 27 Dec. 2006 the entire contents of which are hereby incorporated by reference.

### BACKGROUND OF THE INVENTION

1. Field of the Invention

The present invention relates to a method for forming an insulating film in such a manner that the properties of the insulating film are improved.

2. Description of the Related Art

In recent years, the intervals between wires have been made smaller with the miniaturization and speeding up of elements. When the intervals between wires are smaller, the size of the capacitance C between wires, which is inversely proportional to the intervals between wires, increases. When the capacitance C between wires increases, a problem arise such that the delay in the RC signal in the wires increases. Therefore, low dielectric materials (low-k materials) are adopted for the interlayer insulating films, in order to lower the capacitance C between wires by lowering the dielectric constant ∈ (capacitance C between wires is proportional to dielectric constant ∈). Furthermore, methods for converting interlayer insulating films to porous films (see for example Japanese Examined Patent Publication No. 1998-092804 and Japanese Unexamined Patent Publication No. 1997-232302) are conventionally used in order to lower the dielectric constant.

However, there is a problem with interlayer insulating films (insulating films with a low dielectric constant) formed of such materials with a low dielectric constant, such that the mechanical strength as defined by the Young's modulus lowers to approximately 15% or less in comparison with the case where the insulating film is formed of an oxide film doped with fluorine. Therefore, there is a problem, such that the interlayer insulating film may be easily peeled from the interface, particularly the corners of the chip. This results from the strength of adhesion being weak, due to the low density of the insulating film with a low dielectric constant and damage caused to the chip at the time of dicing. Such interlayer insulating films which being peeled at the time of assembly and subsequent mounting, or using of a product causes disorder in LSI.

As the method for improving the quality of such insulating films with a low dielectric constant, methods for enhancing an insulating film by enhancing cross linking in the film through irradiation with ultraviolet rays or plasma treatment after formation of the film are disclosed (see for example Japanese Unexamined Patent Publication 2006-165573 and Japanese Unexamined Patent Publication 2006-086449).

In accordance with the methods described in the above Japanese Unexamined Patent Publication 2006-165573 and Japanese Unexamined Patent Publication 2006-086449, cross linking is enhanced in the film by carrying out at least one type of treatment from among removal of unreacted residual material which remains within the insulating film during the process for forming an insulating film, termination of uncombined bonds (dangling bonds) which exist in the insulating film, and removal of OH groups that have been adsorbed on the dangling bonds, and therefore, enhancing of the insulating film and a process for dehydrating the film can be carried out at the same time.

The methods described in the above Japanese Unexamined Patent Publication 2006-165573 and Japanese Unexamined Patent Publication 2006-086449, however, provide a configuration where a process for irradiation with ultraviolet rays or plasma treatment is carried out after the formation an insulating film, and therefore, the performance in terms of removal lowers deeper inside from the surface of the insulating film, and in such locations, the strength of the film cannot be sufficiently increased, due to the presence of reactive materials and dangling bonds, such as of Si—C and Si—H, and there is a risk that the properties may deteriorate, due to the inclusion of water resulting from such unreacted residual materials or uncombined bonds bonding with OH groups inside the film.

### SUMMARY OF THE INVENTION

In view of the foregoing problems, an object of the present invention is to provide a method for forming an insulating film according to which enhancing of the film and removal of water and OH groups from the film can be efficiently carried out.

In order to achieve this object, the method for forming an insulating film according to the present invention is firstly characterized in that the process for forming an insulating film on a substrate has: a first step of forming a first insulating film of which the thickness is smaller than a desired film thickness; and a second step of inducing at least one process from among a process for removing unreacted residual material in the first insulating film, a process for terminating uncombined bonds in the first insulating film, and a process for removing OH groups that have been adsorbed in the first insulating film without exposure to the air after the completion of the first step, and the first step and the second step are repeated several times until the first insulating film is deposited to the desired film thickness.

The method for forming an insulating film according to the present invention is firstly characterized as described above, and thus, the first step of depositing a first insulating film and the process for removing unreacted residual material formed in the first insulating film are carried out without exposure to the air, and therefore, there is no risk of water in the air being adsorbed on unreacted residual material. In addition, the first step and the second step are repeated several times, and thus, a process for removal or a process for termination of uncombined bonds is carried out in the entirety of the region in the direction of the depth of the formed first insulating film, in addition to the vicinity of the surface of the first insulating film, after the film has been deposited to a desired thickness, and therefore, enhancing of the film and a dehydration process are carried out in deep locations, in addition to in the vicinity of the surface, so that the quality of the film is increased. In particular, in the case where the first insulating film is an insulating film with a low dielectric constant, the film quality is high when the film is formed using the method for forming an insulating film according to the present invention, and therefore, the problem of the interlayer insulating film being peeled at the time of assembly and subsequent mounting, or using of a product can be solved in LSI where the first insulating film is used as an interlayer insulating film.

Accordingly, when an insulating film with a low dielectric constant formed using the method for forming an insulating film firstly characterized as described above is formed between a lower layer wire and an upper layer wire and used as an interlayer insulating film, it becomes possible to manufacture a highly integrated LSI where suppression of signal delay and increase in the quality of the interlayer insulating film are both achieved.

In addition, the method for forming an insulating film according to the present invention, in addition to being firstly characterized as described above, is secondly characterized in that the second step carries out at least one type of treatment from among heat treatment, treatment through irradiation with ultraviolet rays and plasma treatment.

When the present invention is secondly characterized as described above, the second step is for inducing at least one type of treatment from among treatment through removal of unreacted residual material in the first insulating film, treatment through termination of uncombined bonds in the first insulating film, and treatment through removal of OH groups that have been adsorbed in the first insulating film, and as a result, enhancing of the first insulating film and dehydration of the film are carried out, so that an insulating film having high quality can be formed.

In addition, the method for forming an insulating film according to the present invention, in addition to being firstly and secondly characterized as described above, is thirdly characterized in that the second step is carried out in any gas atmosphere from among NH₃, N₂, He, O₂, H₂, Ar and the material gases used in the first step.

In addition, the method for forming an insulating film according to the present invention, in addition to any one of being firstly, secondly or thirdly characterized as described above, is fourthly characterized in that the second step is carried out at the same temperature or under the same pressure as the first step.

When the method for forming an insulating film according to the present invention is fourthly characterized as described above, treatment through removal or treatment through termination of uncombined bonds is carried out under the same conditions from the first step onward, and therefore, it becomes possible to implement treatment with high efficiency without lowering the performance in terms of treatment.

In addition, the method for forming an insulating film according to the present invention, in addition to any one of being firstly, secondly, thirdly or fourthly characterized as described above, is fifthly characterized in that the second step is carried out within the same reaction chamber as the first step.

In the case where the first step and the second step are not carried out inside the same reaction chamber, it is necessary to move the semiconductor substrate, which is the object of treatment, after the completion of the first step, and in the case where the atmospheric gas during this movement includes OH groups or water, there is a possibility that this may be adsorbed on the unreacted residual material or dangling bonds. When the method for forming an insulating film according to the present invention is thirdly characterized as described above, however, the semiconductor substrate, which is an object of treatment, is not moved between the first step and the second step, and therefore, water or OH groups can be more prevented from being adsorbed in the insulating film. Furthermore, it is not necessary to prepare a dedicated unit for the second step, and therefore, the cost of manufacture can be reduced.

In addition, the method for forming an insulating film according to the present invention, in addition to any one of being firstly to fifthly characterized as described above, is sixthly characterized in that a third step of forming a second insulating film after the completion of the second step is provided, and the first step, the second step and the third step are repeated several times without exposure to the air until the total thickness of the first insulating film and the second insulating film becomes the desired thickness.

When the method for forming an insulating film according to the present invention is sixthly characterized as described above, the second insulating film deposited between the first insulating film and the first insulating film prevents unreacted residual material and OH groups that have been released in the second step from being adsorbed again, and therefore, the effects of preventing OH groups from being adsorbed in the first insulating film can be more enhanced.

In addition, the method for forming an insulating film according to the present invention, in addition to being sixthly characterized as described above, is seventhly characterized in that the thickness of the second insulating film formed in the third step is smaller than the thickness of the first insulating film formed in the first step immediately before.

In addition, the method for forming an insulating film according to the present invention, in addition to being sixthly and seventhly characterized as described above, is eighthly characterized in that the second step is carried out in any gas atmosphere from among NH₃, N₂, He, O₂, H₂, Ar, the material gases used in the first step and the material gases used in the third step.

The configuration of the present invention makes it possible to form an insulating film where the film is enhanced and water and OH groups are efficiently removed from the film.

### BRIEF DESCRIPTION OF THE DRAWINGS

FIGS. 1A to 1H are schematic cross sectional views each showing a process of a method for forming an insulating film according to the present invention;

FIGS. 2A to 2F are schematic cross sectional views each showing a process of the method for forming an insulating film according to the present invention;

FIGS. 3A to 3D are schematic cross sectional views each showing a process of the method for forming an insulating film according to the present invention; and

FIG. 4 is a flow chart showing each step in the method for forming an insulating film according to the present invention.

### DETAILED DESCRIPTION OF THE INVENTION

In the following, the embodiments of the method for forming an insulating film (hereinafter appropriately referred to as “method of the present invention”) are described in reference to the drawings. Here, in the following, a process for wires including the step of forming an insulting film using the method of the present invention is cited as an example of the embodiment according to the method for the present invention for description.

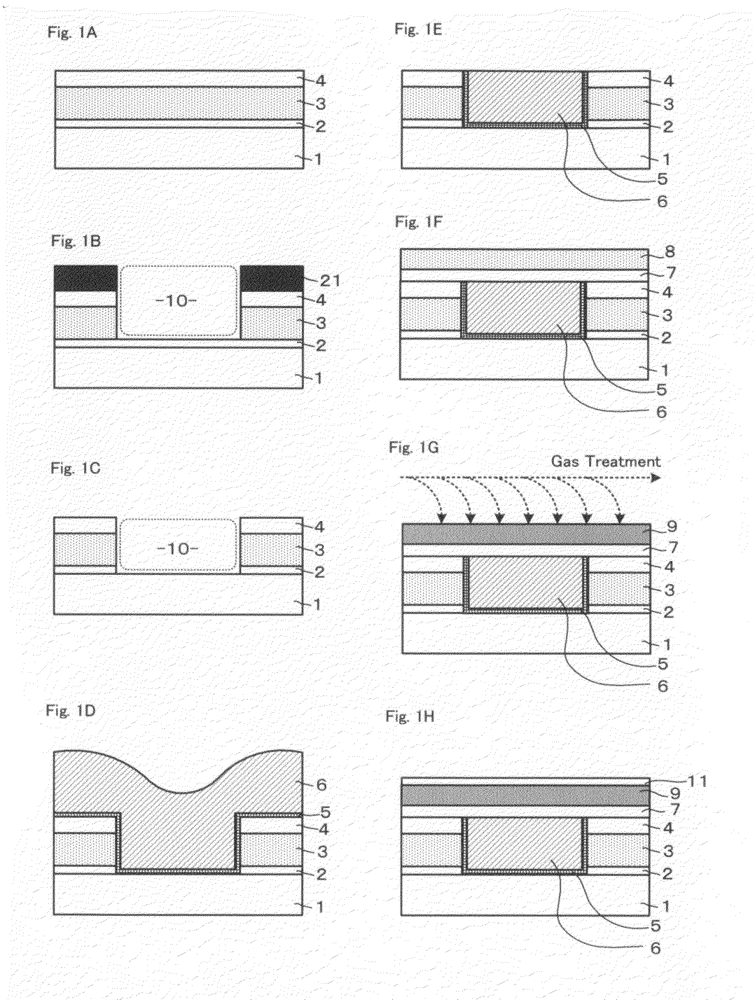

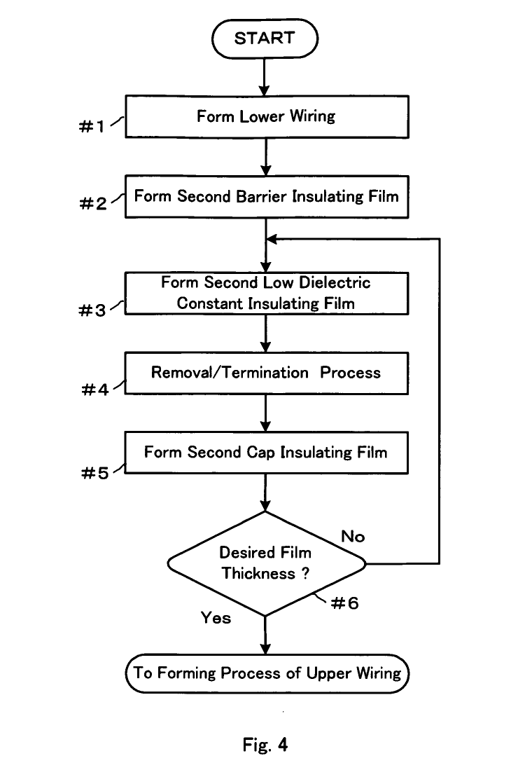

FIGS. 1A to 1H, 2A to 2F and 3A to 3D are schematic cross sectional views showing the multilayer wire structure in each step, including the steps for forming an insulating film according to the method of the present invention (the drawings are shown on three sheets of paper due to restrictions in terms of the size of the paper), and FIG. 4 is a flow chart showing the steps in the method of the present invention. The respective steps in the following description indicate the corresponding steps in the flow chart shown in FIG. 4. In addition, a typical structure is shown in the respective schematic cross sectional views of FIGS. 1A to 1H, 2A to 2F and 3A to 3D, and the scale in terms of the dimensions of the actual structure and the scale in the drawings do not necessarily correspond. Here, the flow chart in FIG. 4 shows only the steps for forming an interlayer insulating film which relate directly to the method of the present invention.

First, as shown in FIG. 1A, an insulating film (for example SiO₂ film) is deposited on a semiconductor substrate and a base insulating film 1 is formed. Next, a first barrier insulating film 2, a first low dielectric constant insulating film 3 and a first cap insulating film 4 are formed in sequence. The first barrier insulating film 2 can be formed by depositing SiC film having a relative dielectric constant of approximately 3.5, for example, and a thickness of approximately 25 nm in accordance with a plasma CVD (Chemical Vapor Deposition) method, for example, the first low dielectric constant insulating film 3 can be formed by depositing SiOC film having a relative dielectric constant of approximately 2.5 and a thickness of approximately 200 nm to 300 nm in accordance with the plasma CVD method, and the first cap insulating film 4 can be formed by depositing SiO₂ film having a relative dielectric constant of approximately 4.2 and a thickness of approximately 20 nm to 100 nm in accordance with the plasma CVD method.

Next as shown in FIG. 1B, the first cap insulating film 4 and the first low dielectric insulating film 3 are etched using a first resist mask 21 which is patterned in the same form as lower layer wires which are subsequently formed as a mask, and thus, a trench 10 is created. At this time, the first barrier insulating film 2 remains unetched (functions as an etching stopper film). After that, the first resist mask 21 is removed, and then, a cleaning process is carried out, in order to remove residues.

Next, as shown in FIG. 1C, the first barrier insulating film 2 is removed through etching using the first cap insulating film 4 as a hard mask, and the upper surface of the base insulating film 1 is exposed.

Next, as shown in FIG. 1D, a first barrier metal film 5 is formed of, for example, Ta/TaN with a thickness of approximately 5 nm to 10 nm on the entire surface in accordance with a sputtering method, and after that, a first wire material film 6 is formed on the entire surface. As the first wire material film 6, a Cu film having a thickness of approximately 500 nm, for example, can be deposited. At this time, a configuration can be provided where the trench 10 is completely filled in with the Cu film by depositing a seed Cu film in accordance with the sputtering method, and after that, depositing a Cu film in accordance with an electrical field plating method.

Next, as shown in FIG. 1E, the first wire material film 6 and the first barrier metal film 5 that have been deposited on the first cap insulating film 4 are polished and removed in accordance with, for example, a CMP (Chemical Mechanical Polishing) method, so that the surface is flattened. As a result, a lower layer wire is formed inside the trench 10 (step #1).

Next, as shown in FIG. 1F, a second barrier insulating film 7 is formed so as to coat the entire surface, including the first cap insulating film 4, the first barrier metal film 5 and the first wire material film 6 (step #2), and furthermore, a second low dielectric constant insulating film 8 is formed thereon (step #3). Here, the second barrier insulating film 7 may be formed by depositing the same material as for the first barrier insulating film 2 to approximately the same thickness (25 nm). In addition, the second low dielectric constant insulating film 8 may be formed of the same material (SiOC film) as for the first low dielectric constant insulating film 3, and in this case, the film can be formed in accordance with a plasma CVD method using an organic silane, such as monomethylsilane, (SiH₃CH₃) and N₂O or O₂ as a material gas under such conditions that the temperature of the substrate is 400° C., an RF voltage with a frequency of 13.56 MHz is applied, and the pressure is 1 Torr. The thickness of the second low dielectric constant insulating film 8 formed at this time is smaller than the thickness of the interlayer insulating film to be formed between the first wire material film 6 and the second wire material film to be formed over the first wire material film 6 in a subsequent step (hereinafter appropriately referred to as “desired film thickness”), and may be, for example, approximately ⅓ of the desired film thickness. This desired film thickness may be, for example, approximately 300 nm to 400 nm.

Next, O₂ gas treatment is carried out with the substrate at the same temperature and under the same pressure as in the step for film formation in step #3 (step #4). This gas treatment induces removal of at least one of unreacted materials, uncombined bonds (dangling bonds), such as of Si—C and Si—H, and OH groups adsorbed on the dangling bonds, which remain in the second low dielectric constant insulating film 8 formed in step #3, and thus, a stable low dielectric constant insulating film 9 is formed, as shown in FIG. 1G (hereinafter simply referred to as “second low dielectric constant insulating film 9”).

Next, as shown in FIG. 1H, a second cap insulating film 11 is formed with the substrate at the same temperature and under the same pressure as in the treatment in steps #3 and #4 (step #5). At this time, a film having a thickness of approximately 10 nm can be deposited using, for example, trimethylsilane (SiH(CH₃)₃) as a material gas in accordance with the plasma CVD method, so that the second cap insulating film 11 is formed.

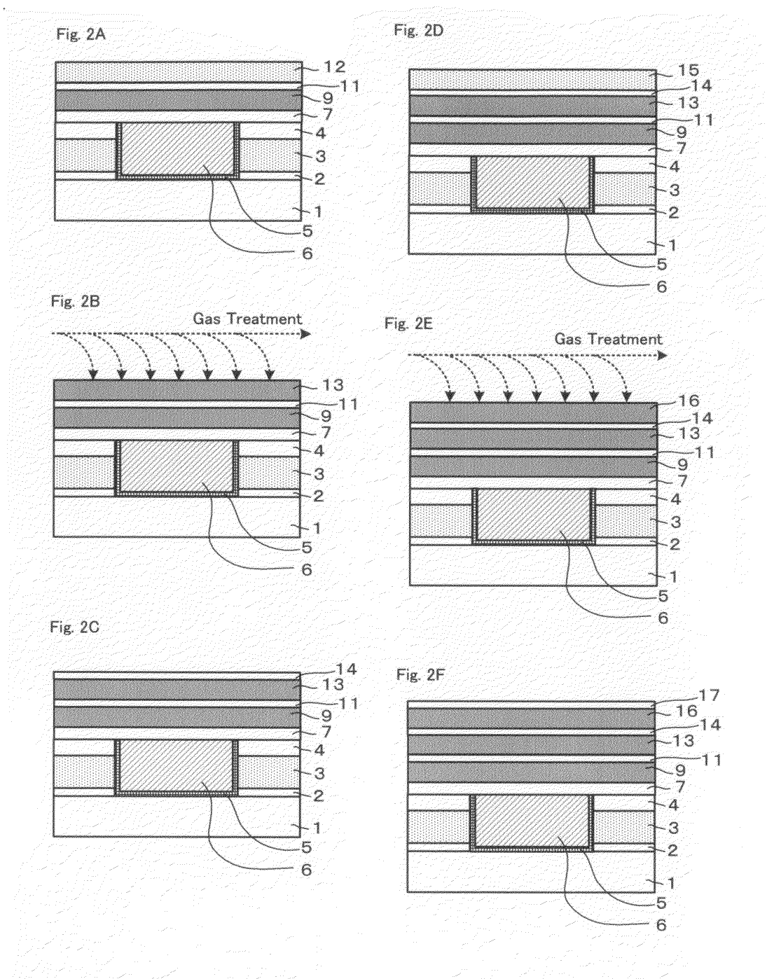

Next, as shown in FIG. 2A, a second low dielectric constant insulating film 12 is formed in the same manner as with the formation of the second low dielectric constant insulating film 8 in step #3. The thickness of the deposited film may be approximately the same as the thickness of the second low dielectric constant insulating film 8 that is deposited in step #3. After that, as shown in FIG. 2B, O₂ gas treatment is carried out in the same manner as in step #4, so that at least one of release of unreacted residual material in the second low dielectric constant insulating film 12, termination of dangling bonds and release of OH groups adsorbed on the dangling bonds is induced, and after that, as shown in FIG. 2C, a second cap insulating film 14 having approximately the same thickness is formed in accordance with the same method as in step #5. After that, the respective steps in step #3 to step #5 are repeated in the same manner in this order (see FIGS. 2D, 2E and 2F), and thus, an insulating film layer where second low dielectric constant insulating films (9, 13, 16) and second cap insulating films (11, 14, 17) on which the process for removing unreacted residual material and the like has been carried out are alternately layered is formed. Here, each of these steps in step #3 to step #5 may be repeated in the same reaction chamber, without exposure to the air until the total thickness of the insulating film layer formed of the second low dielectric constant insulating films and the second cap insulating films becomes the desired film thickness (NO in step #6). At this time, in the case where the total thickness of the already deposited films described above is close to the desired film thickness, the second low dielectric constant insulating film or the second cap insulating film which is subsequently deposited is adjusted to an appropriate thickness so that the total film thickness becomes approximately the same as the desired film thickness.

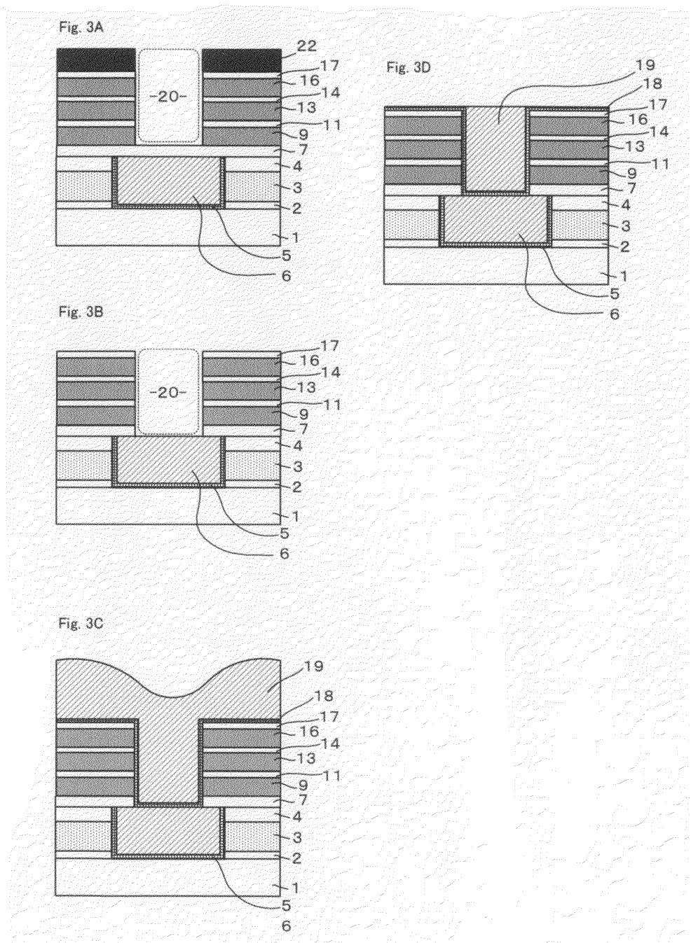

When the total thickness of the second low dielectric constant insulating films and the second cap insulating films reaches the desired film thickness (YES in step #6), the procedure goes to the step of forming an upper layer wire (step #7). That is, as shown in FIG. 3A, first, the second low dielectric constant insulating films (9, 13, 16) and the second cap insulating films (11, 14, 17) are etched using a second resist mask 22 which is patterned in the same form as electrodes between wires which are subsequently formed as a mask, and thus, a via hole 20 is created in a location above the first wire material film 6. At this time, the second barrier insulating film 7 remains unetched (functions as an etching stopper film). After that, the second resist mask 22 is removed, and then, a cleaning process is carried out, in order to remove residue.

Next, as shown in FIG. 3B, the second barrier insulating film 7 is removed through etching using the second cap insulating film 17 as a hard mask, and the upper surface of the first wire material film 6 is exposed.

Next, as shown in FIG. 3C, a second barrier metal film 18 having a thickness of approximately 5 nm to 10 nm is formed of, for example, Ta/TaN on the entire surface in accordance with the sputtering method, in the same manner as with the first barrier metal film 5, and after that, a second wire material film 19 is formed on the entire surface. As the second wire material film 19, a Cu film having a thickness of approximately 500 nm, for example, can be deposited in the same manner as with the first wire material film 6, and as a result of this step for film formation, the via hole 20 is filled in with the second wire material film 19. After that, as shown in FIG. 3D, the second wire material film 19 and the second barrier metal film 18 deposited on the second cap insulating film 17 are polished and removed in accordance with, for example, a CMP method, so that the surface is flattened. As a result, an electrode between wires is formed inside the via hole 20.

After that, in the case where an additional wire layer is formed in an upper layer, the respective steps of the step #2 to step #6, as well as the step of forming an upper wire (the step of forming a second wire material film 19), may be repeated.

According to the method of the present invention, a process for forming an insulating film, at least one of removal of unreacted residual material, termination of dangling bonds, and a process for removing OH groups that have been adsorbed on the dangling bonds (hereinafter generally referred to as “a process for removing unreacted residual material and the like”) are carried out without exposure to the air within the same unit, and therefore, there is no risk of water or OH groups in the air being adsorbed on the unreacted residual material or the dangling bonds. In addition, though in the case where the process for removing unreacted residual material and the like is carried out after the deposition of insulating film having a desired film thickness, the effects of this process are apparent in the region in the vicinity of the film surface, the performance in terms of removing unreacted residual material or terminating dangling bonds lowers deeper inside the insulating film, and as a result, in some cases, some unreacted residual material, dangling bonds or OH groups adsorbed on the dangling bonds remain inside the film. In this case, there is a possibility that sufficient mechanical strength for the insulating film cannot be secured due to the presence of unreacted material or dangling bonds which remain inside the insulating film, and furthermore, there is a possibility that the presence of OH groups adsorbed on the dangling bonds, or OH groups absorbed on unreacted residual material or the dangling bonds in subsequent steps may allow water to be contained inside the insulating film during the subsequent process, and thus, the water may cause the properties of the device to deteriorate. According to the method of the present invention, however, the low dielectric constant insulating film between the second wire material film 19, which becomes the upper layer wire, and the first wire material 6, which becomes the lower layer wire, is formed in several stages (9, 13, 16) and subjected to the process for removing unreacted residual material and the like at each stage, thus, the process has been carried out on the entire region of the formed insulating film in the direction of the depth. Accordingly, removal of unreacted material and termination of dangling bonds can be sufficiently carried out even within the low dielectric constant insulating film which is formed near the location where the lower layer wire is formed, and therefore, the insulating film can be sufficiently enhanced and a dehydration process can be sufficiently carried out inside the film. As a result, the quality of the insulating film can be more increased in comparison with conventional methods.

In addition, according to the method of the present invention, the second cap insulating film is formed between the second low dielectric constant insulating film and the second low dielectric constant insulating film (step #5), and thus, effects of preventing removed unreacted material or OH groups from being adsorbed again are gained, and therefore, the insulating film can be more enhanced and the dehydration process for the film can be more improved.

### OTHER EMBODIMENTS

In the following, other embodiments are described.

(1) Though the foregoing embodiments have such a configuration that at least one process (hereinafter simply referred to as “a process for removing unreacted residual material and the like”) from among removal of unreacted residual material, termination of dangling bonds and a process for removing OH groups that have been adsorbed on the dangling bonds is induced by carrying out O₂ gas treatment on the second low dielectric constant insulating film in step #4, such a configuration that the process for removing unreacted residual material and the like is induced by carrying out plasma treatment in an H₂ gas atmosphere may be provided. In this case, dangling bonds created in the second low dielectric constant insulating film are terminated with hydrogen. In addition, such a configuration that the process for removing unreacted residual material and the like is induced by carrying out similar treatment in a gas atmosphere, such as of NH₃, N₂, He or Ar, or the same gas atmosphere as that used in the process for forming the second low dielectric constant insulating film.

In addition, though in the foregoing embodiments, plasma treatment is carried out in step #4, the process for removing unreacted residual material and the like may be induced by carrying out heat treatment or irradiation treatment using ultraviolet rays in a gas atmosphere as that described above. In the case where heat treatment is carried out, for example, heat treatment may be carried out for approximately 30 seconds to 60 seconds with the temperature of the substrate at 350° C. to 650° C. In addition, in the case where irradiation treatment is carried out using ultraviolet rays, though there currently exists no treatment unit which makes it possible for a process for depositing an insulating film in accordance with a CVD method and irradiation treatment using ultraviolet rays to be carried out within the same unit (chamber), under circumstances where such a unit exists, ultraviolet rays may be radiated with a wavelength of 100 nm to 400 nm and an irradiation power of approximately 10 mW/cm² to 100 mW/cm² (under the same conditions as in the case where a process for removal is carried out through irradiation with ultraviolet rays in an ultraviolet ray radiating unit after the substrate is once taken out from the CVD unit). Heat treatment or irradiation treatment using ultraviolet rays is carried out under these conditions, and thus, a process for removing unreacted residual material or a termination process is carried out on the second low dielectric constant insulating film.

(2) The materials used for the respective insulating films and the respective wire material films in the foregoing embodiments are examples, and not limited to those cited. As the first low dielectric constant insulating film and the second low dielectric constant insulating film, for example, SiOF, SiOCF, SiCF, SiCO, SiCH, SiCOH and porous SiO₂ may be used. In this case, material gases corresponding to the formation of the respective insulating films (or example Si(CH₃)₄, Si(OC₂H₅)₄, (CH₃)₃SiNHSi(CH₃)₃, —[Si(CH₃)₂O]₄—, CF_{X} and the like) may be used.

Furthermore, though a case where a low dielectric constant insulating film is used as an interlayer insulating film is described in the above embodiments, the method for forming an insulating film according to the present invention, where treatment for inducing the process for removing unreacted residual material and the like is carried out when an insulating film is formed as described above, is not limited to formation of a low dielectric constant insulating film, and can be used in cases where a silicon oxide film, which is a general interlayer insulating film, is formed, as well as in cases where a so-called high dielectric constant film (high-k film) of which the dielectric constant is higher than that of silicon oxide films is formed. A film of SiO₂ may be formed to a thickness of approximately one third of the desired film thickness in accordance with a plasma CVD method using tetraethoxysilane (Si(OC₂H₅)₄) as a material gas under such conditions that the temperature of the substrate is 400° C., an RF voltage with a frequency of 13.56 MHz is applied and the pressure is 1 Torr in step #3, for example.

(3) Though in the foregoing embodiments, the second cap insulating film is formed after the process for removing unreacted residual material and the like is induced in step #4, the second low dielectric constant insulating film may be subsequently formed without forming a second cap insulating film. That is, in this case, the step of forming a second low dielectric constant insulating film (step #3) and the processing step such as removal of unreacted residual material (step #4) are repeated until the second low dielectric constant insulating film reaches a desired thickness. In this case also, the second low dielectric constant insulating film is formed in several stages and subjected to the process for removing unreacted residual material and the like at each stage, thus the process has been carried out on the entire region of the formed insulating film in the direction of the depth, and thus, the insulating film can be enhanced and a dehydration process can be carried out inside the film in the direction of the depth. Here, in the case where the step #5 is carried out after the completion of step #4, effects of preventing removed unreacted material and OH groups from being adsorbed again are gained, as described above, and therefore, it can be expected that the foregoing effects in terms of the second low dielectric constant insulating film are further enhanced.

(4) Though the foregoing embodiments provide a configuration where no process for removing unreacted residual material and the like is carried out on the first low dielectric constant insulating film 3 formed before the deposition of the first wire material film 6 which becomes lower layer wires, the configuration may allow the same process as the process carried out on the second low dielectric constant insulating film 8 to be carried out on the first low dielectric constant insulating film 3. That is, the first low dielectric constant insulating film 3 is deposited to a film thickness that is smaller than the desired film thickness, and then, the process for removing unreacted residual material and the like is carried out through O₂ gas treatment and the like, and after that, a first cap insulating film 4 is deposited, and this sequence of processes is repeated several times until the total film thickness of the first low dielectric constant insulating film 3 and the first cap insulating film 4 reaches a desired film thickness, and then, the step of creating a trench 10 can be carried out.

(5) Though in the foregoing embodiments, a case where an insulating film sandwiched between a lower layer wire and an upper layer is formed is described, the invention can be used in a process for forming other insulating films where it is necessary to enhance the insulating film or carry out a dehydration process inside the film, in addition to the foregoing case.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A method for forming an insulating film comprising
a process for forming an insulating film on a substrate, the process including:
a first step of forming a first insulating film of which a thickness is smaller than a desired film thickness; and
a second step of inducing at least one process from among a process for removing unreacted residual material in the first insulating film, a process for terminating uncombined bonds in the first insulating film, and a process for removing OH groups that have been adsorbed in the first insulating film, without exposure to the air after completion of the first step, wherein
the first step and the second step are repeated several times until the first insulating film is deposited to the desired film thickness.

2. The method for forming an insulating film according to claim 1, wherein the second step carries out at least one type of treatment from among heat treatment, treatment through irradiation with ultraviolet rays and plasma treatment.

3. The method for forming an insulating film according to claim 1, wherein the second step is carried out in any gas atmosphere from among NH₃, N₂, He, O₂, H₂, Ar and material gases used in the first step.

4. The method for forming an insulating film according to claim 1, wherein the second step is carried out at the same temperature or under the same pressure as the first step.

5. The method for forming an insulating film according to claim 1, wherein the second step is carried out within the same reaction chamber as the first step.

6. The method for forming an insulating film according to claim 1 comprising a third step of forming a second insulating film after completion of the second step, wherein
the first step, the second step and the third step are repeated several times without exposure to the air until a total thickness of the first insulating film and the second insulating film becomes the desired thickness.

7. The method for forming an insulating film according to claim 6, wherein a thickness of the second insulating film formed in the third step is smaller than a thickness of the first insulating film formed in the first step immediately before.

8. The method for forming an insulating film according to claim 6, wherein the second step is carried out in any gas atmosphere from among NH₃, N₂, He, O₂, H₂, Ar, material gases used in the first step and material gases used in the third step.
